(19) United States
(12) Patent Application Publication
(10) Pub. No.: US 2016/0190007 A1
(43) Pub. Date: Jun. 30, 2016

(54) A METHOD FOR MICROVIA FILLING BY COPPER ELECTROPLATING WITH TSV TECHNOLOGY FOR 3D COPPER INTERCONNECTION AT HIGH ASPECT RATIO

(71) Applicant: SHANGHAI SINYANG SEMICONDUCTOR MATERIALS CO., LTD., Shanghai (CN)

(72) Inventors: Su WANG, Shanghai (CN); Xianxian YU, Shanghai (CN); Li MA, Shanghai (CN); Yanyan LI, Shanghai (CN)

(21) Appl. No.: 14/909,307

(22) PCT Filed: Dec. 10, 2013
(86) PCT No.: PCT/CN2013/001524

§ 371 Date: Feb. 1, 2016

(30) Foreign Application Priority Data
Aug. 8, 2013 (CN) 201310343314.7

(51) Int. Cl. H01L 21/768; C25D 5/48; C25D 5/34; C25D 7/12; C25D 3/38

(52) U.S. Cl. CPC H01L 21/76879; C25D 7/12; C25D 3/38; C25D 5/34; C25D 5/48; H01L 21/76883; H01L 21/76898

(57) ABSTRACT

A method for microvia filling by copper electroplating with a TSV technology for a 3D copper interconnection at a high aspect ratio, which includes: Step 1: formulating an electroplating solution of a copper methyl sulfonate system, Step 2: wetting the microvias of the TSV technology by means of an electroplating pre-treatment, Step 3: charging into the grooves, completing the ultra-low current diffusion, so that the copper ions and the additives are rationally distributed at the surface and the interior of the microvias of the TSV technology, Step 4: connecting the wafer for the TSV technology to the cathode of a power source, fully immersing the electroplating surface of the wafer in the electroplating solution, and electroplating with a step-by-step current method of rotating or stirring the cathode, the current density of the plating conditions is 0.01-10A/dm2 and the temperature is 15-30° C., Step 5: after the electroplating, washing the wafer completely clean with deionized water, and drying it by spinning or blowing. The method for microvia filling by copper electroplating with a TSV technology for a 3D copper interconnection at a high aspect ratio has a high via-filling speed, a thin copper layer on the surface, no risk of creating voids and cracks, and can achieve the complete filling of microvias having an aspect ratio of more than 10:1 which are extremely difficult to fill.

### TECHNICAL FIELD

This invention involves a method micro-electroplating method of copper plating step by step for 3D TSV technology, in particular, relates to a method for microvia filling by copper electroplating with TSV technology for 3D copper interconnection at high aspect ratio.

### BACKGROUND ART

TSV (Through-Silicon-Via) technology is the latest technology of making vertical breakover between chips, and wafers to realize the interconnection between chips. Different from the IC packaging bonding and the superposition technique using convex points, TSV can make the chips stacked in the three-dimensional directions of the maximum density, the minimum size, and significantly improve the operation speed of the chips and reduce power consumption.

Since the copper electroplating deposition process has been widely used in the semiconductor technology, it is believed that the technique could be transformed from copper damascene to through-hole filling TSV. However, after testing many traditional copper plating systems, the effect has not been satisfactory. Seams, voids, electrolyte impurities and other defects may affect the reliability of interconnection. Therefore, there is a need for a perfect integration of new high-purity chemicals and electroplating process with excellent performance to significantly improve the inverted filling performance.

Commercial electroplating additive present can be in the design of three kinds of organic part usually contains: accelerator, inhibitor and leveling agent (the additives for copper interconnection metal plating). The key factors ensuring the successful filling of via holes are the stability of the process and the speed control. The characteristics of the complete process are the no-void filling with good adhesive agents and the withstanding to the minimum load necessary for the following chemical mechanical polishing (CMP). The control of speed could reduce the deposition time o f this technology.

Shape of the side wall (the tapered sidewall is relatively easy to implement electroplating); the continuity and adhesiveness of the barrier layer and the seed layer; the good wettability of the feature size (especially under the high aspect ratio of the feature size); and the optimized process (additives and process conditions) , all of these factors may contribute to the full filling without void.

For the application of TSV, size means filling duration and productivity, which will be reflected by the cost eventually. To improve productivity and reduce cost, the filling duration shall be reduced, or the feature size shall be reduced, or the faster process shall be developed.

In general, in all different types of 3D technologies, the copper interconnection TSV vertical integration of the current semiconductor industry is considered to be the most advanced, is also one of the most popular topics. The copper electroplating and deposition is feasible in the TSV application, and can be used for a wide range of feature sizes. With appropriate designing combinations of additives and process conditions, the reliable TSV structure without void could be realized.

The key element of the TSV electroplating and copper filling technique is that the copper shall be deposited in the high aspect ratio microvias without voids and seams During the electro-deposition, if the copper is plated on both sides and the bottom surface of the channel at the same deposition rate, also that is the Conformal Plating, seams may be easily formed in the center of the channel. If the deposition rate of the upper part of the channel is higher than the lower part, there will be holes in the channel. Only if the deposition rate at the bottom of the channel is higher than the sides of the channel, the fully filling of the copper in the channel can be ensured. This fully filling method is called super-conformal plating, also called Bottom-up filling

How to use appropriate process control to achieve super-conformal plating is the key for the filling of high aspect ratio microvias filling. Technically, the electroplating performance of high aspect ratio microvias depends on the equipment capacity, pre-treatment conditions, the system of the electroplating liquid, size distribution of microvias, distribution of hole types and electroplating parameters and the like.

### DISCLOSURE OF THE INVENTION

The purpose of the invention is to provide a a method for high aspect ratio (>10:1) TSV microporous electroplating fill process , to realize bottom-up filling, reduce the possibility of seams or voids, improve the hole filing speed, make the surface copper thin, reduce the post manufacturing cost and provide technical guarantee for the 3D-TSV encapsulation mass production.

In order to achieve the above-mentioned purpose, the invention has provided a method for microvia filling by copper electroplating with a TSV technology for a 3D copper interconnection at a high aspect ratio. The method comprises:

Step 1: formulating an electroplating solution of a copper methyl sulfonate system;

Step 2: wetting the microvias of the TSV technology by means of an electroplating pre-treatment;

Step 3: charging into the grooves, completing the ultra-low current diffusion (i.e., ions from the solution diffuse to the electrode to produce the electrode reaction), giving the full diffusion time so that the copper ions and the additives are rationally distributed at the surface and the interior of the microvias of the TSV technology;

Step 4: the step-by-step current plating step, that is, the normal electroplating process: connecting the wafer for the TSV technology to the cathode of a power source, fully immersing the electroplating surface of the wafer in the electroplating solution, and electroplating with a step-by-step current method of rotating or stirring the cathode, the current density of the plating conditions is 0.01-10 A/dm2 and the temperature is 15-30° C.; preferably electroplating conditions for current density range is 0.3-1.0 A/dm², the temperature is 20-25° C.;

Step 5: after the electroplating, washing the wafer completely clean with deionized water, and drying it by spinning or blowing.

The said electroplating solution of a copper methyl sulfonate system in step 1 contains by quality volume ratio: 30-130 g/L of copper ions and 5-50 g/L of methanesulfonic acid as well as 20-150 mg/L of chlorine ions.

The said electroplating solution also contains by volume ratio: 1-30 mg/L of accelerator, 5-50 mg/L of inhibitor and 1-30 mg/L of leveling agent. Under the action of the electric field, the accelerator, inhibitor and leveling agent could make a synergistic effect, give full play to the competition mechanism, to obtain the TSV sample with excellent performance and rapid deposition.

The said accelerator contains one or several kinds from the combined sulfur compounds of poly dithiobis propanesulfonic acid disodium, phenyl dithio propanesulfonic acid sodium, 3-S-isothiuronium propanesulfonic acid sodium salt, 3-mercapto-l-propanesulfonate sodium salt, alcohlpropane sulfonate sodium, isothiourea propanesulfonic acid sodium salt, dimethyl-dithiocarbamyl sulfonic acid sodium, 3-(benzothiazol-2-ylthio)-1-propanesulfonate sodium salt, methyl-(sulfopropyl) disulfide disodium salt, methyl- (sulfopropyl) trisulfide disodium salt. The said accelerator could accelerate the plating speed of the low potential region, and improve the luminance and refine the grains, which could be used with the non-ionic surface active agent, polyamine compounds and other thio compounds in the typical copper plating formulation.

The said inhibitor contains one or several kinds from the combined copolymer of polyethylene oxide with a molecular weight of 2000-20000, polyethylene glycol dimetyl ether, poly propylene glycol, polypropylene oxide glycol, mercaptobenzimidazole, and benzotriazole.. The said inhibitor may be used to wet and inhibit the deposition of the plated layer on the high potentialregion, refine the grains and inhibit the deposition speed of the copper in the region with high current density.

The said leveling agent contains one or several kinds from the combined thiourea compounds, alkyl pyridine compounds, Janus Green B and the polyamine derivatives of fatty alcohol alkoxylates. The said leveling agent has such functions as wetting and leveling, which could impede the deposition of the plated layers by sterically hindered or electrochemical action, so as to assist the refining of the grains and ensure the uniform thickness of the plated layers under the high-speed deposition condition.

The said electroplate pre-treatment in Step 2 is to use one or several kinds of the combined ultrasonic, mega-sonic vibration or vacuum means to treat the microvias before the electroplating.

The said electroplating method is suitable for the microvias with the diameter of 5-30 μm, the depth of 30-300 μm and the aspect ratio of higher than 10:1.

The duration of the said electroplating is 60-70 minutes. Compared with the prior art, the present invention has the following advantages and technical effects:

1. The step-by-step current method is used for the electroplating filling, which could realize the bottom-up filing by adjusting the parameters timely according to the types of the holes, featuring rapid hole filling speed, thin surface copper and no risk of void and seam. In this way, the holes of difficult types with the aspect ratio of higher than 10:1 could be completely filled. The duration and surface copper thickness are halved compared to the traditional additives, reducing the TSV electroplating duration and the post treatment CMP cost and improving the production efficiency greatly.

2. The plating solution of the invention has simple formulation, easy maintenance, and not produce harmful chemicals to the environment.

3. The TSV electroplating processes using traditional additives may require 120 minutes to fill the holes with the diameter of 10 μm and depth of 100 μm, which has poor stability and the risk of void with the copper thickness of 6-10 μm. For such holes(the diameter of 10 μm and depth of 100 μm), the electroplating process of this invention may only require 60 minutes to complete the bottom-up filling with the thickness of the surface copper layer of 2-4 μm, greatly reducing the filling duration and the cost of the consequent CMP process.

### BRIEF DESCRIPTION OF THE DRAWINGS

FIG. 1 is a schematic diagram of pre-electroplating hole pattern of the invention.

FIG. 2 is a schematic diagram of the electroplating fill of the invention.

FIG. 3 is a schematic diagram of the cross section after electroplating effect of the invention.

FIG. 4 is the X-ray detection effect a schematic diagram of the invention.

### DESCRIPTION OF THE PREFERRED EMBODIMENTS

The following illustration with figures will make a further description to the embodiments of this present invention.

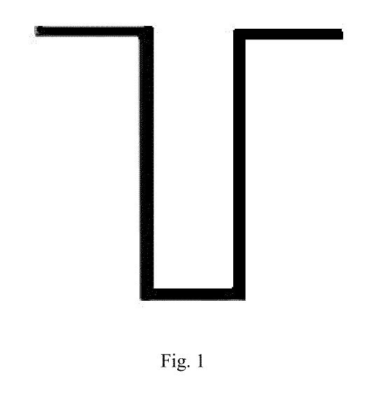

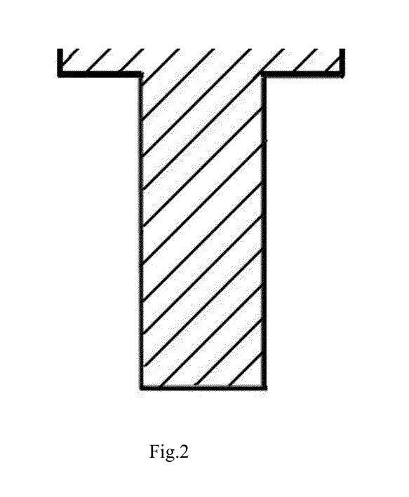

As shown in FIG. 1 and FIG. 2, the present invention provides the method for TSV microvia filling by copper electroplating for a 3D copper interconnection at a high aspect ratio, it need to electroplate copper filling in the TSV holes shown in the figures. The used power supply is the high precision DC electroplating power.

The method provided in the present invention for microvia filling by copper electroplating with a TSV technology for a 3D copper interconnection at a high aspect ratio, comprises:

Step 1: formulating an electroplating solution of a copper methyl sulfonate system, which contains by quality volume ratio: 30-130 g/L of copper ions and 5-50 g/L of methanesulfonic acid as well as 20-150 mg/L of chlorine ions.

The electroplating solution also contains by volume ratio: 1-30 mg/L of accelerator, 5-50 mg/L of inhibitor and 1-30 mg/L of leveling agent.

The accelerator could accelerate the plating speed of the low potential region, and improve the luminance and refine the grains, which could be used with the non-ionic surface active agent, polyamine compounds and other thio compounds in the typical copper plating formulation. The accelerator contains one or several kinds from the combined sulfur compounds of poly dithiobis propanesulfonic acid disodium, phenyl dithio propanesulfonic acid sodium, 3-S-isothiuronium propanesulfonic acid sodium salt, 3-mercapto-1-propanesulfonate sodium salt, alcohlpropane sulfonate sodium, isothiourea propanesulfonic acid sodium salt, dimethyl-dithiocarbamyl sulfonic acid sodium, 3-(benzothiazol-2-ylthio)-1-propanesulfonate sodium salt, methyl- (sulfopropyl) disulfide disodium salt, methyl- (sulfopropyl) trisulfide disodium salt.

The inhibitor may be used to wet and inhibit the deposition of the plated layer on the high potential region, refine the grains and inhibit the deposition speed of the copper in the region with high current density. The inhibitor contains one or several kinds from the combined copolymer of polyethylene oxide with a molecular weight of 2000-20000, polyethylene glycol dimetyl ether, poly propylene glycol, polypropylene oxide glycol, mercaptobenzimidazole, and benzotriazole.

The leveling agent has such functions as wetting and leveling, which could impede the deposition of the plated layers by sterically hindered or electrochemical action, so as to assist the refining of the grains and ensure the uniform thickness of the plated layers under the high-speed deposition condition. The leveling agent contains one or several kinds from the combined thiourea compounds, alkyl pyridine compounds, Janus Green B and the polyamine derivatives of fatty alcohol alkoxylates.

Under the action of the electric field, the accelerator, inhibitor and leveling agent could make a synergistic effect, give full play to the competition mechanism , to obtain the TSV sample with excellent performance and rapid deposition.

The process of formulating the electroplating solution is as follows: prepare based plating solution containing 30-130 g/L copper ions and 5-50 g/L the ultra-pure methanesulfonic acid; then add the 1-30 ml/L accelerator, 5-50 ml/L inhibitor and 1-30 mg/L leveling agent; and stir the solution uniformly.

Step 2, wetting the microvias of the TSV technology by means of an electroplating pre-treatment. The electroplate pre-treatment is to use one or several kinds of the combined ultrasonic, megasonic vibration or vacuum means to treat the microvias before the electroplating.

Step 3: charging into the grooves, completing the ultra-low current diffusion (i.e., ions from the solution diffuse to the electrode to produce the electrode reaction), giving the full diffusion time so that the copper ions and the additives are rationally distributed at the surface and the interior of the microvias of the TSV technology.

Step 4: the step-by-step current plating step, that is, the normal electroplating process: connecting the wafer for the TSV technology to the cathode of a power source, fully immersing the electroplating surface of the wafer in the electroplating solution, and electroplating with a step-by-step current method of rotating or stirring the cathode. Preferably electroplating conditions for current density range is 0.3-1.0 A/dm2, the temperature is 20-25° C.

Based on the proper diffusion, the current density during the electroplating shall be controlled to enable the intended function of the additive, so as to ensure the growth of the wall copper without changing the function of the additive and realize the bottom-up filling.

The current density of the plating conditions is 0.01-10 A/dm² and the temperature is 15-30° C. Preferably electroplating conditions for current density range is 0.3-1.0 A/dm², the temperature is 20-25° C.

Step 5, after the electroplating, washing the wafer completely clean with deionized water, and drying it by spinning or blowing.

The electroplating method is suitable for the microvias with the diameter of 5-30 μm, the depth of 30-300 μm and the aspect ratio of higher than 10:1. The duration of the electroplating is 60-70 minutes.

The method provided in the present invention for microvia filling by copper electroplating with a TSV technology for a 3D copper interconnection at a high aspect ratio, uses the step-by-step electroplating method, which could adjust the current density according to the hole diameter and aspect ratio. For example, the step-by-step electroplating parameters: 0.01ASD 120s; 0.1ASD 600s; 0.4ASD 3000s, 0.01ASD 120s; 1.0 ASD 300s; 0.7ASD 600s; 0.5ASD 2400s; 0.3ASD 1200s. ASD is the unit of the current density in the electroplating, lASD=1 ampere/square decimeter.

The method could realize the bottom-up filing by adjusting the parameters timely according to the types of the holes, featuring rapid hole filling speed, thin surface copper and no risk of void and seam. In this way, the holes of difficult types with the aspect ratio of higher than 10:1 could be completely filled.

### Example 1

Take 10×100 μm holes for example.

Pre-treatment: vacuumize for 5 minutes at the vacuum degree of 0-0.2 torr, and immerse with pure water for 1-10 minutes.

Based methanesulfonic acid plating solution preparation: 100 g/L Cu²⁺, 30 g/L ultra-pure methanesulfonic acid and 30 mg/L Cl⁻.

Additive preparation: Accelerator: inhibitor: leveling agent =5:10:5

Experiment conditions: temperature =25° C.; Flow =15 L/min; cathode rotation =50 RPM.

Electroplating parameters: 0.01ASD 120s; 0.1ASD 600s; 0.4ASD 3000s

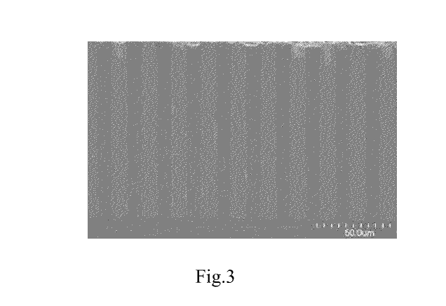

Results: see FIG. 3, Fully filling, no default, copper layer thickness <3 μm.

### Example 2

Take 15×150 μm holes for example.

Pre-treatment: vacuumize for 5 minutes at the vacuum degree of 0-0.2 torr, and immerse with pure water for 1-10 minutes.

Based methanesulfonic acid plating solution preparation: 90 g/L Cu²⁺, 20 g/L ultra-pure methanesulfonic acid and 20 mg/L Cl⁻.

Additive preparation: Accelerator: inhibitor: leveling agent =3:10:7

Experiment conditions: temperature =22-25° C.; Flow =15 L/min; cathode rotation =50 RPM.

Electroplating parameters: 0.01ASD 120s; 1.0 ASD 300s; 0.7ASD 600s; 0.5ASD 2400s; 0.7ASD 300s; 0.3ASD 1200s

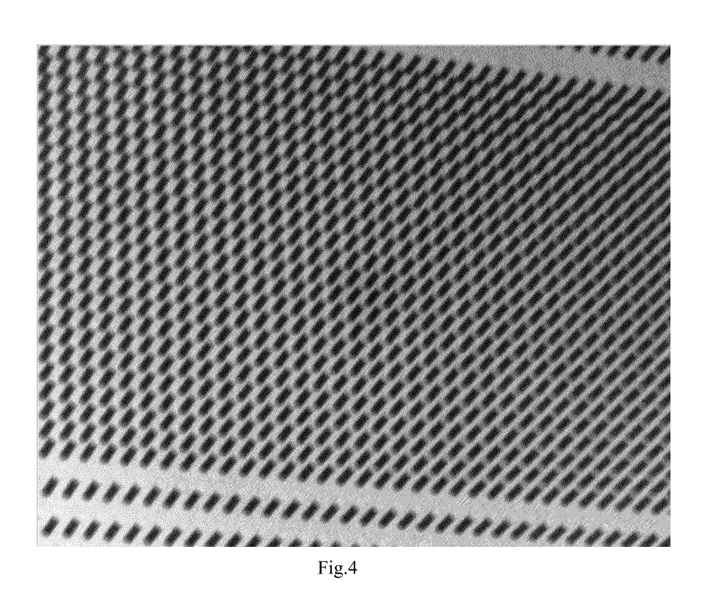

Results: see FIG. 4, full filling without default

Treatment after electroplating: Wash the wafer with deionized water for 2 minutes and dry it.

Analysis, test and evaluation of the plating samples obtained from the example 1 and example 2:

1. Section analysis: make sections from the samples according to the hole patterns, seal the samples with specific epoxy curing material for polishing and check for the electroplating flaws under metalloscope or under SEM. See FIG. 3 for results.

2. None intrusive detection: Check the filling performance and electroplating uniformity of the microvias with the X-ray detection equipment. See FIG. 4 for the results.

The method provided in the present invention for microvia filling by copper electroplating with a TSV technology for a 3D copper interconnection at a high aspect ratio, could manufacture the TSV sample of smooth appearances and good uniformity without void or seam, which could meet the requirements.

Despite the detailed introduction to the invention as above, the above introduction could not be considered as the limitation to the invention. After the technical personnel in the field have read the above contents, the modifications and alternations of the invention will be obvious. Therefore, the protection scope of the invention shall be limited by the attached claims.

1. A method for microvia filling by copper electroplating with TSV technology for 3D copper interconnection at high aspect ratio, the method comprising:
step 1: formulating an electroplating solution of a copper methyl sulfonate system;
step 2: wetting the microvias of the TSV technology by means of an electroplating pre-treatment;
step 3: charging into the grooves, completing the ultra-low current diffusion , so that the copper ions and the additives are rationally distributed at the surface and the interior of the microvias of the TSV technology;
step 4: connecting the wafer for the TSV technology to the cathode of a power source, fully immersing the electroplating surface of the wafer in the electroplating solution, and electroplating with a step-by-step current method of rotating or stirring the cathode, the current density of the plating conditions is 0.01-10 A/dm² and the temperature is 15-30° C.;
step 5: after the electroplating, washing the wafer completely clean with deionized water, and drying it by spinning or blowing.

2. The method for microvia filling by copper electroplating with TSV technology for 3D copper interconnection at high aspect ratio of claim 1, wherein, said electroplating solution of a copper methyl sulfonate system in step 1 contains by quality volume ratio: 30-130 g/L of copper ions and 5-50 g/L of methanesulfonic acid as well as 20-150 mg/L of chlorine ions.

3. The method for microvia filling by copper electroplating with TSV technology for 3D copper interconnection at high aspect ratio of claim 2, wherein, said electroplating solution also contains by volume ratio: 1-30 mg/L of accelerator, 5-50 mg/L of inhibitor and 1-30 mg/L of leveling agent.

4. The method for microvia filling by copper electroplating with TSV technology for 3D copper interconnection at high aspect ratio of claim 3, wherein, said accelerator contains one or several kinds from the combined sulfur compounds of poly dithiobis propanesulfonic acid disodium, phenyl dithio propanesulfonic acid sodium, 3-S-isothiuronium propanesulfonic acid sodium salt, 3-mercapto-1-propanesulfonate sodium salt, alcohlpropane sulfonate sodium, isothiourea propanesulfonic acid sodium salt, dimethyl-dithiocarbamyl sulfonic acid sodium, 3-(benzothiazol-2-ylthio)-1-propanesulfonate sodium salt, methyl- (sulfopropyl) disulfide disodium salt, methyl- (sulfopropyl) trisulfide disodium salt.

5. The method for microvia filling by copper electroplating with TSV technology for 3D copper interconnection at high aspect ratio of claim 3, wherein, said inhibitor contains one or several kinds from the combined copolymer of polyethylene oxide with a molecular weight of 2000-20000, polyethylene glycol dimetyl ether, poly propylene glycol, polypropylene oxide glycol, mercaptobenzimidazole, and benzotriazole.

6. The method for microvia filling by copper electroplating with TSV technology for 3D copper interconnection at high aspect ratio of claim 3, wherein, said leveling agent contains one or several kinds from the combined thiourea compounds, alkyl pyridine compounds, Janus Green B, and the polyamine derivatives of fatty alcohol alkoxylates.

7. The method for microvia filling by copper electroplating with TSV technology for 3D copper interconnection at high aspect ratio of claim 1, wherein, said electroplate pre-treatment in step 2 is to use one or several kinds of the combined ultrasonic, megasonic vibration or vacuum means to treat the microvias before the electroplating.

8. The method for microvia filling by copper electroplating with TSV technology for 3D copper interconnection at high aspect ratio of claim 1, wherein, said electroplating method is suitable for the microvias with the diameter of 5-30 μm, the depth of 30-300 μm and the aspect ratio of higher than 10:1.

9. The method for microvia filling by copper electroplating with TSV technology for 3D copper interconnection at high aspect ratio of claim 8, wherein, the duration of the said electroplating is 60-70 minutes.
